(19) United States
(12) Patent Application Publication
(10) Pub. No.: US 2025/0306137 A1
(43) Pub. Date: Oct. 2, 2025

(54) MULTIPLE-SENSITIVITY SENSOR WITH DYNAMIC OFFSET CORRECTION AND HIGH DYNAMIC RANGE

(71) Applicant: Allegro MicroSystems, LLC, Manchester, NH (US)

(72) Inventors: Emil Pavlov, Heidelberg (DE); Rostislav Doganov, Schwetzingen (DE)

(73) Assignee: Allegro MicroSystems, LLC, Manchester, NH (US)

(21) Appl. No.: 18/619,265

(22) Filed: Mar. 28, 2024

(51) Int. Cl. G01R 33/07; H03F 3/45

(52) U.S. Cl. CPC G01R 33/07; H03F 3/45475

(57) ABSTRACT

A method is provided for use in a sensor, comprising: generating a sensing signal by using one or more sensing elements; amplifying the sensing signal by using a first gain to produce, at least in part, a first amplified signal, the first amplified signal having a first offset; amplifying the sensing signal by using a second gain to produce, at least in part, a second amplified signal, the second amplified signal having a second offset; generating an adjusted signal based on the first amplified signal, the second amplified signal, the first gain, and the second gain, the adjusted signal approximating a difference between the second amplified signal and an offset of the second amplified signal; and using the adjusted signal to generate an output of the sensor.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with proximity or motion of a target object. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a method is provided for use in a sensor, comprising: generating a sensing signal by using one or more sensing elements; amplifying the sensing signal by using a first gain to produce, at least in part, a first amplified signal, the first amplified signal having a first offset; amplifying the sensing signal by using a second gain to produce, at least in part, a second amplified signal, the second amplified signal having a second offset; generating an adjusted signal based on the first amplified signal, the second amplified signal, the first gain, and the second gain, the adjusted signal approximating a difference between the second amplified signal and an offset of the second amplified signal; and using the adjusted signal to generate an output of the sensor.

According to aspects of the disclosure, a sensor is provided, comprising: one or more sensing elements configured to generate a sensing signal; one or more amplifiers configured to: (i) amplify the sensing signal by using a first gain to produce, at least in part, a first amplified signal, the first amplified signal having a first offset, and (ii) amplify the sensing signal by using a second gain to produce, at least in part, a second amplified signal, the second amplified signal having a second offset; and a processing circuitry that is configured to: (i) generate an adjusted signal based on the first amplified signal, the second amplified signal, the first gain, and the second gain, the adjusted signal approximating a difference between the second amplified signal and an offset of the second amplified signal; and (ii) use the adjusted signal to generate an output of the sensor.

According to aspects of the disclosure, a system is provided, comprising: means for generating a sensing signal by using one or more sensing elements; means for amplifying the sensing signal by using a first gain to produce, at least in part, a first amplified signal, the first amplified signal having a first offset; means for amplifying the sensing signal by using a second gain to produce, at least in part, a second amplified signal, the second amplified signal having a second offset; and means for generating an adjusted signal based on the first amplified signal, the second amplified signal, the first gain, and the second gain, the adjusted signal approximating a difference between the second amplified signal and an offset of the first amplified signal.

According to aspects of the disclosure, a method for use in a sensor, comprising: generating a sensing signal by using one or more sensing elements; amplifying the sensing signal by using a first gain to produce, at least in part, a first amplified signal; amplifying the sensing signal by using a second gain to produce, at least in part, a second amplified signal, the second gain being smaller than the first gate; generating an adjusted signal based the first gain, the second gain, and at least one of the first amplified signal and the second amplified signal; and using the adjusted signal to generate an output of the sensor, wherein, when the second amplified signal is less than a threshold, generating the adjusted signal includes scaling the first amplified signal based on a ratio of the first gain and the second gain, and setting the adjusted signal to equal the scaled first amplified signal, and, when the second amplified signal is greater than or equal to the threshold, generating the adjusted signal includes setting the adjusted signal to equal the second amplified signal.

### BRIEF DESCRIPTION OF THE DRAWINGS

The foregoing features may be more fully understood from the following description of the drawings in which:

FIG. 1A is a diagram of an example of a sensor, according to aspects of the disclosure;

FIG. 1B is a diagram of an example of a sensor, according to aspects of the disclosure;

FIG. 1C is a graph illustrating aspects of the operation of a sensor, according to aspects of the disclosure;

FIG. 2A is a flowchart of an example of a process, according to aspects of the disclosure;

FIG. 2B is a flowchart of an example of a process, according to aspects of the disclosure;

FIG. 2C is a flowchart of an example of a process, according to aspects of the disclosure; and

FIG. 3 is a diagram of an example of a sensor, according to aspects of the disclosure;

### DETAILED DESCRIPTION

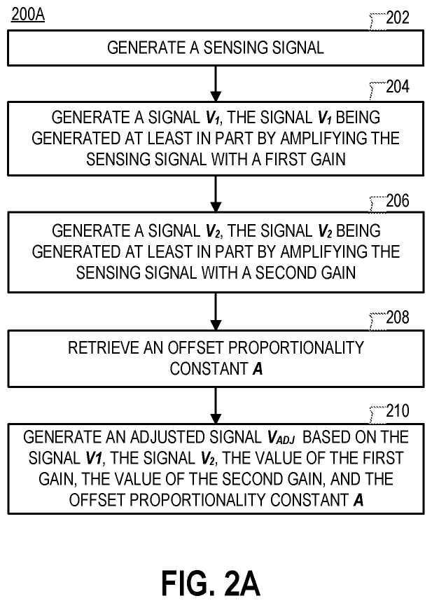

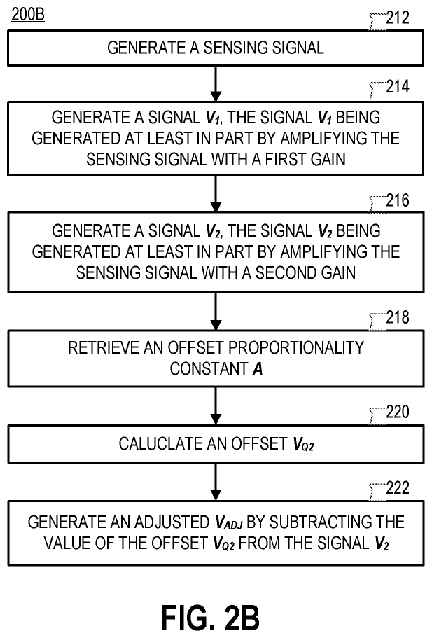

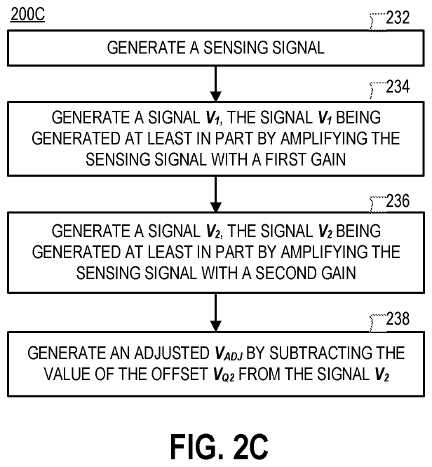

According to aspects of the disclosure, a sensor is provided that is configured to measure a physical quantity by utilizing two or more sensitivities concurrently. In some implementations, the sensor may be an integrated current sensor, simultaneously measuring current through two distinct sensitivities or internal amplifier gains. Specifically, the sensor may implement a method for dynamically correcting the zero-current offset voltage by employing the simultaneous measurement of current through two different sensitivities. The method may be executed as discussed further below with respect to FIG. 2A and/or FIG. 2B. Using the method is advantageous because it may eliminate (or at least reduce) the need for zero-input offset calibration in the sensor or the necessity for quiescent voltage trimming. This is in contrast to conventional sensors which require the zero-input signal to be measured and trimmed to a desired value at the time of the sensor's calibration.

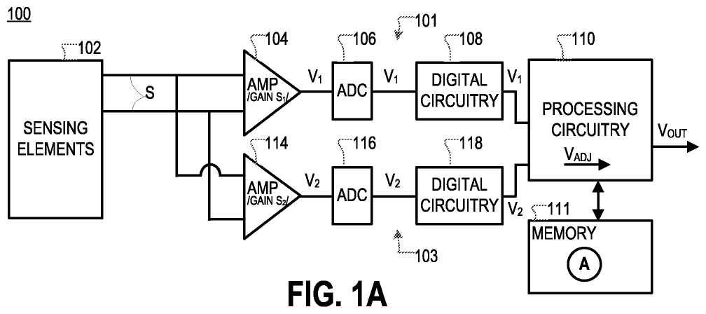

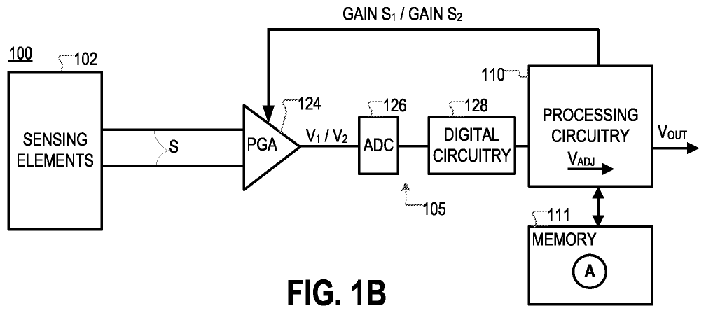

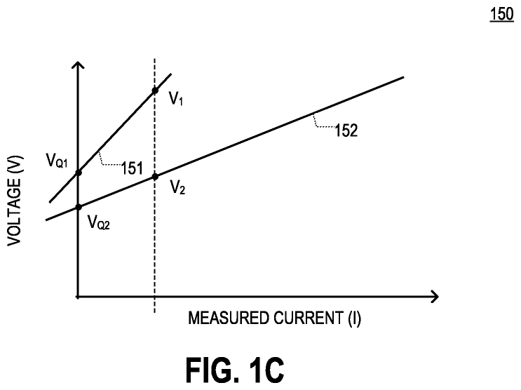

FIG. 1 is a diagram of a magnetic field sensor 100, according to aspects of the disclosure. According to the present example, sensor 100 is a current sensor. However, the present disclosure is not limited to sensor 100 being any specific type of sensor. As illustrated, sensor 100 may include sensing elements 102, signal paths 101 and 103, processing circuitry 110, and a memory 111. Signal path 101 may include an amplifier 104, an analog-to-digital converter (ADC) 106, digital circuitry 108, and a processing circuitry 110. Signal path 103 may include an amplifier 114, an ADC 116, and digital circuitry 118.

According to the present example, sensing elements 102 include one or more Hall plates. However, alternative implementations are possible in which the sensing elements 102 include one or more giant magnetoresistance (GMR) elements, one or more tunneling magnetoresistance (TMR) elements, and/or any other suitable type of sensing element. The digital circuitry 108 may include one or more of a cascaded integrator-comb (CIC) filter, a temperature correction circuit, a temperature sensor, a bandwidth selection circuit, and or any other suitable type of electronic circuitry that is used in digital sensors. The digital circuitry 118 may include one or more of a cascaded integrator-comb (CIC) filter, a temperature correction circuit, a temperature sensor, a bandwidth selection circuit, and or any other suitable type of electronic circuitry that is used in digital sensors. The processing circuitry 110 may include a general-purpose processor, an application-specific processor, and/or any other suitable type of processing circuitry. Memory 111 may include an Electrically Erasable Programmable Read-Only Memory (EEPROM), and/or any other suitable type of volatile or non-volatile memory.

In operation, sensing elements 102 may generate a sensing signal S. Amplifier 104 may amplify the sensing signal S with a first gain S₁ to generate a first signal V₁. ADC 106 may amplify the signal V₁. Digital circuitry 108 may perform filtering and/or other processing on the signal V₁. Processing circuitry 110 may receive the signal V₁ after it has been digitized and processed by ADC 106 and digital circuitry 108, respectively. Amplifier 114 may amplify the sensing signal S with a second gain S₂ to generate a SECOND signal V₂. ADC 116 may amplify the signal V₂. Digital circuitry 118 may perform filtering and/or other processing on the signal V₂. Processing circuitry 110 may receive the signal V₂ after it has been digitized and processed by ADC 116 and digital circuitry 118, respectively. Processing circuitry 110 may process signals V₁ and V₂ to generate a signal Vout. Signal Vout may be generated in accordance with one of processes 200A and 200B, which are discussed further below with respect to FIGS. 2A and 2B, respectively. According to the present example, signal Vout is output by sensor 100 to another device. However, alternative implementations are possible in which signal Vout is processed internally by sensor 100 to generate another output signal. Stated succinctly, the present disclosure is not limited to any specific method for using signal Vout.

FIG. 1B is a diagram of sensor 100, according to another implementation. The implementation of sensor 100 that is shown in FIG. 1B is nearly identical to the implementation shown in FIG. 1A, but for including a signal path 105 instead of signal paths 101 and 103. As illustrated, signal path 105 may include a programmable gain amplifier (PGA) 124, an ADC 126, and digital circuitry 128. Digital circuitry 128 may include one or more of a cascaded integrator-comb (CIC) filter, a temperature correction circuit, a temperature sensor, a bandwidth selection circuit, and or any other suitable type of electronic circuitry that is used in digital sensors.

Processing circuitry 110 may be configured to set the gain of PGA 124. In operation, processing circuitry 110 may alternate the gain of PGA 124 between the gain S₁ and the gain S₂. PGA 124 may receive the sensing signal S from sensing elements S₂. When the gain of PGA 124 is set to S₁, PGA 124 may generate a signal V₁ and provide the signal V₁ to ADC 126; ADC 126 may digitize the signal V₁ and provide the digitized signal V₁ to digital circuitry 128. Digital circuitry 128 may process the signal V₁ and provide the processed signal V₁ to processing circuitry 110. When the gain of PGA 124 is set to S₂, PGA 124 may generate a signal V₂ and provide the signal V₂ to ADC 126; ADC 126 may digitize the signal V₂ and provide the digitized signal V₂ to digital circuitry 128. Digital circuitry 128 may process the signal V₂ and provide the processed signal V₂ to processing circuitry V₂. In the example of FIG. 2, signal V₁ includes samples of the output of PGA 124 when the gain of PGA 124 is set to S₁ and signal V₂ includes samples of the output of PGA 124 when the gain of PGA 124 is set to S₂. In some implementations, the gain of PGA 124 may alternate between S₁ and S₂ at a frequency of at least double the bandwidth of the sensor.

Processing circuitry 110 may process signals V₁ and V₂ to generate a signal Vout. Signal Vout may be generated in accordance with one of processes 200A and 200B, which are discussed further below with respect to FIGS. 2A and 2B, respectively. According to the present example, signal Vout is output by sensor 100 to another device. However, alternative implementations are possible in which signal Vout is processed internally by sensor 100 to generate another output signal. Stated succinctly, the present disclosure is not limited to any specific method for using signal Vout.

FIG. 1C shows an example of graph 150, which includes curves 151 and 152. Curve 151 is a plot of signal V₁ and curve 152 is a plot of signal V₂. The X-axis of graph 150 represents the value I of the electrical current that is being measured by sensor 100. In the example of FIG. 1, the slope of curve 151 is equal to (or otherwise based on) the gain S₁, and the slope of signal V₂ is equal to, or otherwise based on, the gain S₁. In the example of FIG. 1C, signal V₁ has an offset V_{Q1} and signal V₂ has an offset V_{Q2}.

The offsets V_{Q1} and V_{Q2} may be present in the signals V₁ and V₂, respectively, for various reasons, such as impurities in the materials used to form the sensing elements 102, device geometry and fabrication, magnetic field homogeneity, and others. The presence of such offsets in the signals produced by sensing elements can result introduce inaccuracies in the measurements that are produced by sensing elements (or sensors utilizing the sensing elements). For this reason, magnetic field sensors (as well as other types of sensors) employ various techniques that remove the offset from the signals produced by the sensing elements before the signals are used to produce an output signal.

Processing circuitry 110 employs a process for removing offset from the signals produced by sensing elements by measuring electrical current using two sensitivities at the same time. The two sensitivities that are referred to as the gains S₁ and S₂, which are discussed above with respect to FIGS. 1A-B. The removal of offset is accomplished by using an improved model which is further discussed further below.

According to the model, the values of signals V₁ and V₂ can be represented by equations 1 and 2 below:

$${V}_{1} = I \cdot {s}_{1} + {V}_{Q 1} \qquad ( 1 )$$

$${V}_{2} = I \cdot {s}_{2} + {V}_{Q 2} \qquad ( 2 )$$

where I is the value of the signal being measured, S₁ is the first gain with which the signal S (shown in FIGS. 1A-B) is being amplified, and S₂ is the second gain with which the signal S (shown in FIGS. 1A-B) is being amplified, the value of S₁ is different from the value of S₂ (s₁≠S₂). V_{Q1} is the offset that is present in signal V₁ and V_{Q2} is the offset that is present in signal V₂. In one example, the values of signals V₁ and V₂ in equations 1 and 2 may be generated simultaneously and they may measure the same electrical current value (e.g., see FIG. 1A). In this example, signals V₁ and V₂ may be generated by amplifying the signal using different amplifiers that have different gains (e.g., amplifiers 104 and 114 both of which are shown in FIG. 1A). Alternatively, signals V₁ and V₂ may be generated by using the same amplifier (e.g., amplifier 114 that is shown in FIG. 1B), while switching the gain of the amplifier very rapidly. In this case, the values of signals V₁ and V₂, which are referenced in equations 1 and 2, may be consecutive samples of the output of the amplifier or samples of the output of the amplifier that are captured during the same time window (e.g., a time window having a duration of 50 ms, etc.). In any event, the samples may be captured so closely in time with each other that for the purposes of the present disclosure they are presumed to represent the same electrical current level.

Equations 1 and 2 lead to the identity which is described by equation 3 below:

$$\frac{{V}_{1} - {V}_{Q 1}}{{s}_{1}} = \frac{{V}_{2} - {V}_{Q 2}}{{s}_{2}} \qquad ( 3 )$$

An offset proportionality constant may be defined by Equation 4 as follows:

$$A = \frac{{V}_{Q 1}}{{V}_{Q 2}} \qquad ( 4 )$$

Using equations 1-4, the values of the offsets V_{Q1} and V_{Q2} may be described by equations 5 and 6 below:

$${V}_{{Q}_{1}} = A \frac{{s}_{2} {V}_{1} - {s}_{1} {V}_{2}}{{s}_{2} A - {s}_{1}} \qquad ( 5 )$$

$${V}_{{Q}_{2}} = \frac{{s}_{2} {V}_{1} - {s}_{1} {V}_{2}}{{s}_{2} A - {s}_{1}} \qquad ( 6 )$$

Using Equations 1-6, the offset V_{Q2} may be removed from signal V₂ by using Equation 7 below:

$${V}_{ADJ} = \frac{{V}_{2} - {V}_{{Q}_{2}}}{{s}_{2}} = \frac{{V}_{1} - {AV}_{2}}{{s}_{1} - {As}_{2}} \qquad ( 7 )$$

Equation 7 provides that signal V_{ADJ} is equal to the value of signal V₂ with the offset v_{Q2} removed from it. Equation 7 further provides that the value of signal V_{ADJ} is equal to the quotient of (i) the difference between the value of signal V₂ and the value of signal V₁ as scaled by the offset proportionality constant A, and (ii) the difference between the first gain S₁ and the second gain S₂, as scaled by offset proportionality constant A. In some implementations, the signal VOUT (shown in FIGS. 1A-B) may be the same or equal to the adjusted signal V_{ADJ}. Alternatively, in some implementations, the signal VOUT may be another signal that is generated in part based on the signal V_{ADJ}.

Returning to FIGS. 1A-B, the value of the proportionality constant A may be stored in memory 111. In some implementations, the value of the proportionality constant A may be stored in memory 111 at the factory, and it may be one of the many factory-specified configuration settings of sensor 100. Alternatively, in some implementations, the value of the proportionality constant A may be stored in memory 111 as a result of sensor 100 executing a calibration procedure. The calibration procedure may be performed by sampling the output of sensing elements 102 while no detectable electrical current is present in the vicinity of sensor 100. Moreover, according to the present disclosure, it has been determined that in many practical sensor layouts (i.e., die layouts) the offset proportionality constant may be equal to 1 or be sufficiently close to the value of 1. In other words, in many implementations, it may be possible to omit the value of the proportionality constant A from the calculations described above with respect to equations 1-7.

In some implementations, processing circuitry 110 may execute at least a portion of a process 200A (discussed below with respect to FIG. 2A), which takes advantage of the model described above with respect to equations 1-7. Additionally or alternatively, in some implementations, processing circuitry 110 may execute at least a portion of a process 200B (discussed below with respect to FIG. 2B), which takes advantage of the model described above with respect to equations 1-7. Additionally or alternatively, in some implementations, processing circuitry 110 may execute at least a portion of a process 200C (discussed with respect to FIG. 2C), which capitalizes on the fact that signals V₁ and V₂ have different sensitivities.

FIG. 2A is a flowchart of an example of a process 200A, according to aspects of the disclosure. According to the present example, process 200A is performed by sensor 100. However, the present disclosure is not limited to any specific entity executing the process 200A. In some respects, incorporating process 200A into the operation of a sensor is advantageous because it may eliminate the need for zero-input calibration and/or quiescent voltage trimming.

At step 202, a sensing signal is generated by using one or more sensing elements. According to the present example, the sensing signal is the signal S, which is discussed above with respect to FIGS. 1A-B and it is generated by sensing elements 102. Although in the present example, sensing signal S is generated by magnetic field sensing elements, alternative implementations are possible in which the sensing signal S is generated by another type of sensing element, such as a strain gauge, a thermistor, a light-dependent resistor (LDR), a humidity sensing element, a gas sensor, a force-sensitive resistor, or a flex-sensor. Stated succinctly, the present disclosure is not limited to any specific type of sensing element (or a plurality of sensing elements) being used to generate the sensing signal.

At step 204, a first signal V₁ is generated by amplifying the sensing signal (generated at step 202) with a first gain S₁. In some implementations, the signal V₁ may be generated in the manner discussed above with respect to FIGS. 1A-B.

At step 206, a second signal V₂ is generated by amplifying the sensing signal with a second gain S₂. In some implementations, the signal V₂ may be generated in the manner discussed above with respect to FIGS. 1A-B.

At step 208, an offset proportionality constant A is retrieved from a memory. The offset proportionality constant A may be determined based on the first gain S₁ and the second gain S₂. In some implementations, the offset proportionality constant A may be calculated in accordance with Equation 4.

At step 210, an adjusted signal V_{ADJ} may be calculated based on equation 7. Specifically, the adjusted signal V_{ADJ} may be calculated by evaluating the expression of

$$\frac{{V}_{1} - {AV}_{2}}{{s}_{1} - {As}_{2}} ,$$

which discussed above with respect to equation 7, where V₁ is the value of the first signal, V₂ is the value of the second signal, A is the value of the offset proportionality constant (retrieved at step 208), and S₁ is the first gain that is used generate signal V₁, and S₂ is the second gain that is used to generate signal V₂.

As noted above, the adjusted signal V_{ADJ} may be equal (or sufficiently close to being equal) to the value of signal V₂ with the offset V_{Q2} removed. Calculating the adjusted signal V_{ADJ} in the discussed manner, however, does not require an exact knowledge of the value of signal V_{Q1}.

After the adjusted signal V_{ADJ} is generated it may be output from sensor 100 to external circuitry that is utilizes the measurements taken from sensor 100. For example, the signal V_{ADJ} may be output to the electronic control unit (ECU) of an electric vehicle and/or to another controller. Alternatively, the adjusted signal V_{ADJ} may be used as any offset-adjusted signal would be in the prior art to generate an output signal that is subsequently provided to external circuitry. Stated succinctly, the present disclosure is not limited to any specific method for using the adjusted signal V_{ADJ}.

FIG. 2B is a flowchart of an example of a process 200B, according to aspects of the disclosure. According to the present example, process 200B is performed by sensor 100. However, the present disclosure is not limited to any specific entity executing the process 200A. In some respects, incorporating process 200B into the operation of a sensor is advantageous because it may eliminate the need for zero-input calibration and/or quiescent voltage trimming.

At step 212, a sensing signal is generated by using one or more sensing elements. According to the present example, the sensing signal is the signal S, which is discussed above with respect to FIGS. 1A-B and it is generated by sensing elements 102. Although in the present example, sensing signal S is generated by magnetic field sensing elements, alternative implementations are possible in which the sensing signal S is generated by another type of sensing element, such as a strain gauge, a thermistor, a light-dependent resistor (LDR), a humidity sensing element, a gas sensor, a force-sensitive resistor, or a flex-sensor. Stated succinctly, the present disclosure is not limited to any specific type of sensing element (or a plurality of sensing elements) being used to generate the sensing signal.

At step 214, a first signal V₁ is generated by amplifying the sensing signal (generated at step 212) with a first gain S₁. In some implementations, the signal V₁ may be generated in the manner discussed above with respect to FIGS. 1A-B.

At step 216, a second signal V₂ is generated by amplifying the sensing signal with a second gain S₂. In some implementations, the signal V₂ may be generated in the manner discussed above with respect to FIGS. 1A-B.

At step 218, an offset proportionality constant A is retrieved from memory.

At step 220, the offset of the second signal V₂ is calculated based on the offset proportionality constant A, the first gain S₁, the second gain S₂, the first signal V₁, and the second signal V₂. In some implementations, the value of the offset of the second signal V₂ may be calculated by using equation 6.

At step 222, an adjusted signal V_{ADJ} may be calculated by subtracting the offset (calculated at step 220) from the value of signal V₂ (obtained at step 216). After the adjusted signal V_{ADJ} is generated it may be output from sensor 100 to external circuitry that utilizes the measurements taken from sensor 100. For example, the signal V_{ADJ} may be output to the electronic control unit (ECU) of an electric vehicle and/or to another controller. Alternatively, the adjusted signal V_{ADJ} may be used as any offset-adjusted signal would be in the prior art to generate an output signal that is subsequently provided to external circuitry. Stated succinctly, the present disclosure is not limited to any specific method for using the adjusted signal V_{ADJ}.

FIG. 2C is a flowchart of an example of a process 200C, according to aspects of the disclosure. According to the present example, process 200C is performed by sensor 100. However, the present disclosure is not limited to any specific entity executing the process 200C. In some respects, incorporating process 200C into the operation of a sensor is advantageous because it may increase the dynamic range of the sensor.

At step 232, a sensing signal is generated by using one or more sensing elements. According to the present example, the sensing signal is the signal S, which is discussed above with respect to FIGS. 1A-B and it is generated by sensing elements 102. Although in the present example, sensing signal S is generated by magnetic field sensing elements, alternative implementations are possible in which the sensing signal S is generated by another type of sensing element, such as a strain gauge, a thermistor, a light-dependent resistor (LDR), a humidity sensing element, a gas sensor, a force-sensitive resistor, or a flex-sensor. Stated succinctly, the present disclosure is not limited to any specific type of sensing element (or a plurality of sensing elements) being used to generate the sensing signal.

At step 234, a first signal V₁ is generated by amplifying the sensing signal (generated at step 232) with a first gain S₁. In some implementations, the signal V₁ may be generated in the manner discussed above with respect to FIGS. 1A-B.

At step 236, a second signal V₂ is generated by amplifying the sensing signal with a second gain S₂. In some implementations, the signal V₂ may be generated in the manner discussed above with respect to FIGS. 1A-B.

At step 238, an adjusted signal V_{ADJ} is generated based on signals V₁ and V₂. In some implementations, the adjusted signal V_{ADJ} may be calculated in accordance with equation 8 below:

$${V}_{ADJ} = \{ \begin{matrix}{V}_{1} \frac{{s}_{2}}{{s}_{1}} & for {V}_{2} < {v}_{max 1} \\ {V}_{2} & {v}_{max 1} \leq {V}_{2} < {v}_{max 2}\end{matrix} \qquad ( 8 )$$

where the gain at which the signal V₁ is amplified, S₂ is the gain at which signal V₂ is amplified, vₘₐₓ₁ is a maximum voltage output associated with signal V₁, and vₘₐₓ₂ is a maximum voltage output associated with signal V₂. When signals V₁ and V₂ are generated with two different amplifiers, such as amplifiers 104 and 114 (shown in FIG. 1A), vₘₐₓ₁ may be the maximum voltage output of the amplifier that is used to generate signal V₁ (e.g., amplifier 104) and vₘₐₓ₂ may be the maximum voltage output of the amplifier used to generate signal V₂ (e.g., amplifier 114). In implementations when a PGA is used to generate both of signals V₁ and V₂, such as PGA 124 (shown in FIG. 1B), vₘₐₓ₁ may be the maximum voltage of the PGA when the gain of the PGA is set to S₁, and vₘₐₓ₂ may be the gain of the maximum voltage output of the PGA when the gain of the PGA is set to S₂. According to the present example, the value of vₘₐₓ₁ is smaller than the value of vₘₐₓ₂, and the value of S₁ is greater than the value of S₂ (i.e., vₘₐₓ₁<vₘₐₓ₂ and S₁>S₂).

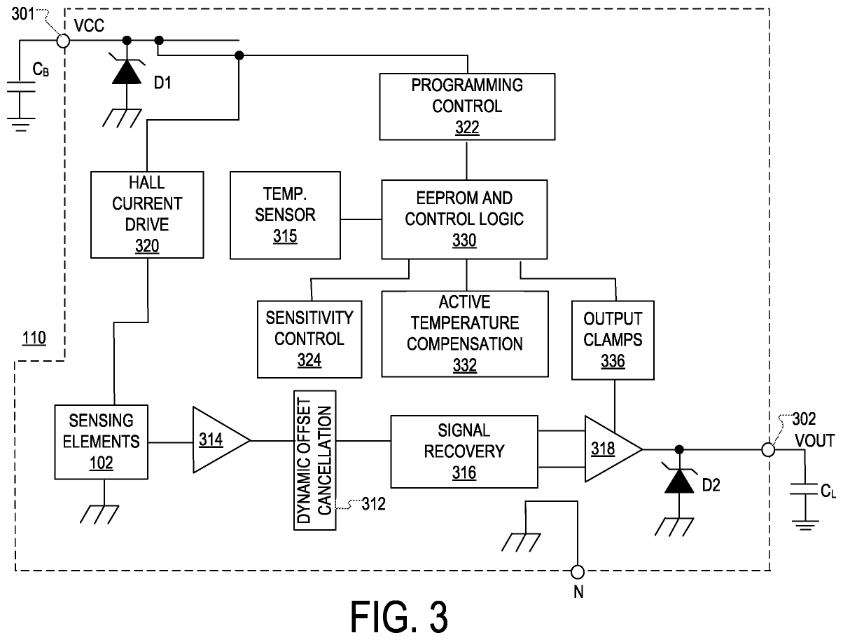

FIG. 3 is a circuit diagram illustrating yet another implementation of sensor 100, according to aspects of the disclosure. In the example, of FIG. 3, sensor 100 is a current sensor and it may be configured to output a signal VOUT that is proportional to ΔB=B_{R}−B_{L} where B_{R} represents the magnetic field incident on one of the magnetic field sensing elements 102 and B_{L} represents magnetic field incident on the other one of the magnetic field sensing elements 102. The sensor output VOUT is also affected by the sensitivity, α, of the signal path and can be represented as follows:

$$VOUT = α \times Δ B \qquad ( 1 )$$

The relationship between the conductor current to be measured and the differential field ΔB can be represented by a coupling coefficient, K(f) as follows:

$$Δ B = K ( f ) \times I \qquad ( 2 )$$

It will be appreciated that coupling coefficient K(f) corresponds to coupling (e.g., transfer of energy, etc.) between a given current sensor and varies with frequency.

The sensor 100 may include a VCC (supply voltage) pin 301, a VOUT (output signal) pin 302. The VCC pin 301 is used for the input power supply or supply voltage for the sensor 100. A bypass capacitor, C_{B}, can be coupled between the VCC pin 301 and ground. The VCC pin 301 can also be used for programming the sensor 100. The VOUT pin 302 is used for providing the output signal VOUT to external circuits and systems (not shown). An output load capacitance C_{L} is coupled between the VOUT pin 302 and ground. According to the present example, sensor 100 can include a first diode D1 coupled between the VCC pin 301 and chassis ground and a second diode D2 coupled between the VOUT pin 302 and chassis ground.

The driver circuit 320 may be configured to drive the magnetic field sensing elements 102. Magnetic field signals generated by the magnetic field sensing elements 102 are coupled to a dynamic offset cancellation circuit 312, which is further coupled to an amplifier 314. The amplifier 314 is configured to generate an amplified signal for coupling to the signal recovery circuit 316. Dynamic offset cancellation circuit 312 may take various forms including processing circuitry that is configured to implement at least in part one of processes 200A-C, which are discussed above with respect to FIGS. 2A-C, respectively. Although dynamic offset cancelation circuit 312 and EEPROM and control logic 330 are depicted as separate entities, in some implementations they may be at least partially integrated with each other. In some implementations, amplifier 314 may be a programmable gain amplifier, and sensitivity control circuit 324 may alternate the gain of amplifier 314 between the values S₁ and S₂, which are discussed above with respect to FIG. 1. In such implementations, dynamic offset cancelation circuit 312 may execute one of processes 200A or 200B to correct the offset in the output of amplifier 314. A regulator (not shown) can be coupled between the supply voltage VCC and ground and to the various components and sub-circuits of the sensor 100 to regulate the supply voltage.

A programming control circuit 322 is coupled between the VCC pin 301 and EEPROM and control logic circuit 330 to provide appropriate control to the EEPROM and control logic circuit. EEPROM and control logic circuit 330 determines any application-specific coding and can be erased and reprogrammed using a pulsed voltage. A sensitivity control circuit 324 can be coupled to the amplifier 314 to generate and provide a sensitivity control signal to the amplifier 314 to adjust the sensitivity and/or operating voltage of the amplifier 314. An active temperature compensation circuit 332 can be coupled to sensitivity control circuit 324, EEPROM and control logic circuit 330, and offset control circuit 334. A push/pull driver circuit 318 (which may be an amplifier) may place the output of the signal recovery circuit 316 on the VOUT pin 302. The active temperature compensation circuit 332 can acquire temperature data from EEPROM and control logic circuit 330 via a temperature sensor 315 and perform necessary calculations to compensate for changes in temperature, if needed. Output clamps circuit 336 can be coupled between the EEPROM and control logic circuit 330 and the driver circuit 318 to limit the output voltage and for diagnostic purposes.

The concepts and ideas presented throughout the disclosure are not limited to current sensor or magnetic field sensors. The concepts and ideas presented throughout the disclosure can be applied to any suitable type of sensor that uses one or more sensing elements. Examples of sensing elements whose output can be corrected by suing the above-discussed concepts and ideas include a strain gauge, a thermistor, a light-dependent resistor (LDR), a humidity sensing element, a gas sensor, a force-sensitive resistor, or a flex-sensor. Stated succinctly, the present disclosure is not limited to the sensors 102 (shown in FIGS. 1A-B) being magnetic field sensors.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”. For example, and without limitation, each or any of sensing elements 102 may include any of the listed magnetic field sensing element types.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A method for use in a sensor, comprising:
generating a sensing signal by using one or more sensing elements;
amplifying the sensing signal by using a first gain to produce, at least in part, a first amplified signal, the first amplified signal having a first offset;
amplifying the sensing signal by using a second gain to produce, at least in part, a second amplified signal, the second amplified signal having a second offset;
generating an adjusted signal based on the first amplified signal, the second amplified signal, the first gain, and the second gain, the adjusted signal approximating a difference between the second amplified signal and an offset of the second amplified signal; and
using the adjusted signal to generate an output of the sensor.

2. The method of claim 1, further comprising, retrieving, from a memory, an offset proportionality constant that is indicative of a ratio between the first offset and the second offset, wherein the adjusted signal is calculated further based on the offset proportionality constant.

3. The method of claim 1, wherein generating the adjusted signal includes calculating the second offset based on the first amplified signal, the second amplified signal, the first gain, and the second gain, and subtracting the second offset from the second amplified signal.

4. The method of claim 1, wherein calculating the adjusted signal includes calculating a ratio between (i) a difference between the first and second amplified signals and (ii) a difference between the first gain and the second gain.

5. The method of claim 1, wherein calculating the adjusted signal includes scaling the second amplified signal based on an offset proportionality constant to produce a scaled second amplified signal, scaling the second gain based on the offset proportionality constant to produce a scaled second gain, and calculating a ratio between (i) a difference between the first amplified signal and the scaled second amplified signal, and (ii) a difference between the second gain and the scaled second gain.

6. The method of claim 1, wherein generating the adjusted signal includes calculating the second offset based on the first amplified signal, the second amplified signal, the first gain, and the second gain, and subtracting the second offset from the second amplified signal, the second offset being calculated in accordance with the equation of:
$${V}_{{Q}_{2}} = \frac{{s}_{2} {V}_{1} - {s}_{1} {V}_{2}}{{s}_{2} A - {s}_{1}}$$
where V_{Q}_{₂} is the second offset, s₁ is the first gain, s₂ is the second gain, V₁ is the first amplified signal, V₂ is the second amplified signal, A is an offset proportionality constant that is indicative of a ration between the first amplified signal and the second amplified signal, and A≥1.

7. The method of claim 1, wherein the adjusted signal is calculated in accordance with the equation of:
$${V}_{ADJ} = \frac{{V}_{1} - {AV}_{2}}{{s}_{1} - {As}_{2}}$$
where V_{ADJ} is the adjusted signal, s₁ is the first gain, s₂ is the second gain, V₁ is the first amplified signal, V₂ is the second amplified signal, A is an offset proportionality constant that is indicative of a ration between the first amplified signal and the second amplified signal, and A≥1.

8. The method of claim 1, wherein each of the sensing elements includes a magnetic field sensing element.

9. The method of claim 1, wherein each of the sensing elements includes one of a strain gauge element, a thermistor, a photoresistor, a humidity sensing element, a gas sensing element, or a force sensing element.

10. The method of claim 1, wherein the first amplified signal is generated by using a first amplifier and the second amplified signal is generated by using a second amplifier.

11. The method of claim 1, wherein:
the first amplified signal and the second amplified signals are generated by using a same programmable gain amplifier; and
the first amplified signal and the second amplified signal are generated by alternating a gain setting of the programmable gain amplifier between at least the first gain and the second gain.

12. A sensor, comprising:
one or more sensing elements configured to generate a sensing signal;
one or more amplifiers configured to: (i) amplify the sensing signal by using a first gain to produce, at least in part, a first amplified signal, the first amplified signal having a first offset, and (ii) amplify the sensing signal by using a second gain to produce, at least in part, a second amplified signal, the second amplified signal having a second offset; and
a processing circuitry that is configured to: (i) generate an adjusted signal based on the first amplified signal, the second amplified signal, the first gain, and the second gain, the adjusted signal approximating a difference between the second amplified signal and an offset of the second amplified signal; and (ii) use the adjusted signal to generate an output of the sensor.

13. The sensor of claim 12, wherein:
the processing circuitry is further configured to retrieve, from a memory, an offset proportionality constant that is indicative of a ratio between the first offset and the second offset, and
the adjusted signal is calculated further based on the offset proportionality constant.

14. The sensor of claim 12, wherein generating the adjusted signal includes calculating the second offset based on the first amplified signal, the second amplified signal, the first gain, and the second gain, and subtracting the second offset from the second amplified signal.

15. The sensor of claim 12, wherein calculating the adjusted signal includes calculating a ratio between (i) a difference between the first and second amplified signals and (ii) a difference between the first gain and the second gain.

16. The sensor of claim 12, wherein calculating the adjusted signal includes scaling the second amplified signal based on an offset proportionality constant to produce a scaled second amplified signal, scaling the second gain based on the offset proportionality constant to produce a scaled second gain, and calculating a ratio between (i) a difference between the first amplified signal and the scaled second amplified signal, and (ii) a difference between the second gain and the scaled second gain.

17. The sensor of claim 12, wherein generating the adjusted signal includes calculating the second offset based on the first amplified signal, the second amplified signal, the first gain, and the second gain, and subtracting the second offset from the second amplified signal, the second offset being calculated in accordance with the equation of:
$${V}_{{Q}_{2}} = \frac{{s}_{2} {V}_{1} - {s}_{1} {V}_{2}}{{s}_{2} A - {s}_{1}}$$
where V_{Q}_{₂} is the second offset, s₁ is the first gain, s₂ is the second gain, V₁ is the first amplified signal, V₂ is the second amplified signal, A is an offset proportionality constant that is indicative of a ration between the first amplified signal and the second amplified signal, and A≥1.

18. The sensor of claim 12, wherein the adjusted signal is calculated in accordance with the equation of:
$${V}_{ADJ} = \frac{{V}_{1} - {AV}_{2}}{{s}_{1} - {As}_{2}}$$
where V_{ADJ} is the adjusted signal, s₁ is the first gain, s₂ is the second gain, V₁ is the first amplified signal, V₂ is the second amplified signal, A is an offset proportionality constant that is indicative of a ration between the first amplified signal and the second amplified signal, and A≥1.

19. The sensor of claim 12, wherein each of the sensing elements includes a magnetic field sensing element.

20. The sensor of claim 12, wherein each of the sensing elements includes one of a strain gauge element, a thermistor, a photoresistor, a humidity sensing element, a gas sensing element, or a force sensing element.

21. The sensor of claim 12, wherein the one or more amplifiers include a first amplifier and a second amplifier, the first amplified signal is generated by using the first amplifier and the second amplified signal is generated by using the second amplifier.

22. The sensor of claim 12, wherein the one or more amplifiers include a programmable gain amplifier, the first amplified signal and the second amplified signals are both generated by using the programmable gain amplifier, and the first amplified signal and the second amplified signal are generated by alternating a gain setting of the programmable gain amplifier between at least the first gain and the second gain.

23. A system, comprising:
means for generating a sensing signal by using one or more sensing elements;
means for amplifying the sensing signal by using a first gain to produce, at least in part, a first amplified signal, the first amplified signal having a first offset;
means for amplifying the sensing signal by using a second gain to produce, at least in part, a second amplified signal, the second amplified signal having a second offset; and
means for generating an adjusted signal based on the first amplified signal, the second amplified signal, the first gain, and the second gain, the adjusted signal approximating a difference between the second amplified signal and an offset of the second amplified signal.

24. A method for use in a sensor, comprising:
generating a sensing signal by using one or more sensing elements;
amplifying the sensing signal by using a first gain to produce, at least in part, a first amplified signal;
amplifying the sensing signal by using a second gain to produce, at least in part, a second amplified signal, the second gain being smaller than the first gate;
generating an adjusted signal based the first gain, the second gain, and at least one of the first amplified signal and the second amplified signal; and
using the adjusted signal to generate an output of the sensor,
wherein, when the second amplified signal is less than a threshold, generating the adjusted signal includes scaling the first amplified signal based on a ratio of the first gain and the second gain, and setting the adjusted signal to equal the scaled first amplified signal, and, when the second amplified signal is greater than or equal to the threshold, generating the adjusted signal includes setting the adjusted signal to equal the second amplified signal.

25. The method of claim 24, wherein the adjusted signal is generated in accordance with the equation of:
$${V}_{ADJ} = \{ \begin{matrix}{V}_{1} \frac{{s}_{2}}{{s}_{1}} & for {V}_{2} < {v}_{max 1} \\ {V}_{2} & {v}_{max 1} \leq {V}_{2}\end{matrix}$$
where s₁ is the first gain, V₁ is the first amplified signal, s₂ is the first gain V₂ is the first amplified signal, and vₘₐₓ₁ is the threshold.

26. The method of claim 24, wherein the first amplified signal is generated by using a first amplifier and the second amplified signal is generated by using a second amplifier.

27. The method of claim 24, wherein the first amplified signal and the second amplified signals are generated by using a same programmable gain amplifier, first amplified signal and the second amplified signal being generated by alternating a gain setting of the programmable gain amplifier between at least the first gain and the second gain.

28. A sensor, comprising:
one or more sensing elements configured to generate a sensing signal;
one or more amplifiers configured to: (i) amplify the sensing signal by using a first gain to produce, at least in part, a first amplified signal, the first amplified signal having a first offset, and (ii) amplify the sensing signal by using a second gain to produce, at least in part, a second amplified signal, the second amplified signal having a second offset; and
a processing circuitry that is configured to: (i) generate an adjusted signal based the first gain, the second gain, and at least one of the first amplified signal and the second amplified signal; and (ii) use the adjusted signal to generate an output of the sensor,
wherein, when the second amplified signal is less than a threshold, generating the adjusted signal includes scaling the first amplified signal based on a ratio of the first gain and the second gain, and setting the adjusted signal to equal the scaled first amplified signal, and, when the second amplified signal is greater than or equal to the threshold, generating the adjusted signal includes setting the adjusted signal to equal the second amplified signal.

29. The method of claim 28, wherein the adjusted signal is generated in accordance with the equation of:
$${V}_{ADJ} = \{ \begin{matrix}{V}_{1} \frac{{s}_{2}}{{s}_{1}} & for {V}_{2} < {v}_{max 1} \\ {V}_{2} & {v}_{max 1} \leq {V}_{2}\end{matrix}$$
where s₁ is the first gain, V₁ is the first amplified signal, s₂ is the first gain V₂ is the first amplified signal, and vₘₐₓ₁ is the threshold.

30. The sensor of claim 28, wherein the one or more amplifiers include a first amplifier and a second amplifier, the first amplified signal is generated by using the first amplifier and the second amplified signal is generated by using the second amplifier.

31. The sensor of claim 28, wherein the one or more amplifiers include a programmable gain amplifier, the first amplified signal and the second amplified signals are both generated by using the programmable gain amplifier, and the first amplified signal and the second amplified signal are generated by alternating a gain setting of the programmable gain amplifier between at least the first gain and the second gain.
